(19) United States
(12) Patent Application Publication
(10) Pub. No.: US 2007/0161246 A1
(43) Pub. Date: Jul. 12, 2007

(54) Process For Selectively Removing Dielectric Material in the Presence of Metal Silicide

(75) Inventors: Yaw S. Obeng, Frisco, TX (US); Jiong-Ping Lu, Richardson, TX (US); Shaofeng Yu, Plano, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/382,639

(22) Filed: May 10, 2006

Related U.S. Application Data
(60) Provisional application No. 60/757,795, filed on Jan. 10, 2006.

(51) Int. Cl. H01L 21/302; H01L 21/461

(52) U.S. Cl. 438/689

(57) ABSTRACT

A method for removing dielectric material 50 from a semiconductor wafer 20 that contains metal silicide 60 or 90. The method includes performing a selective etch 202 of the semiconductor wafer 20 using an organic semi-aqueous solvent-based etchant until the dielectric material 50 is substantially removed and then rinsing 204 the semiconductor wafer 20 including a surface, 63 or 93, of the metal silicide, 60 or 90 respectively, of the semiconductor wafer 20.

### CROSS-REFERENCE TO PROVISIONAL APPLICATION

This application claims the benefit of priority under 35 USC §119(e) of U.S. Provisional Application No. 60/757,795 filed Jan. 10, 2006.

### BACKGROUND OF THE INVENTION

This invention relates to a method of removing dielectric material from a semiconductor wafer while minimizing the removal of exposed metal silicide.

### BRIEF DESCRIPTION OF THE DRAWINGS

FIGS. 1A-1C are cross-sectional diagrams of a process for removing dielectric material from a semiconductor wafer in accordance with an embodiment of the invention.

FIG. 2 is a flow chart illustrating the process flow of the invention.

FIGS. 3A-3C are cross-sectional diagrams of a process for removing dielectric material from a semiconductor wafer in accordance with another embodiment the invention.

FIGS. 4A-4C are cross-sectional diagrams of a process for moving dielectric material from a semiconductor wafer in accordance wit h another embodiment the invention.

FIG. 5A is a cross-sectional diagram of a process for removing dielectric material from a semiconductor wafer in accordance with another embodiment the invention.

### DETAILED DESCRIPTION OF THE INVENTION

The present invention is described with reference to the attached figures, wherein like reference numerals are used throughout the figures to designate similar or equivalent elements. The figures are not drawn to scale and they are provided merely to illustrate the invention. Several aspects of the invention are described below with reference to example applications for illustration. It should be understood that numerous specific details, relationships, and methods are set forth to provide a full understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

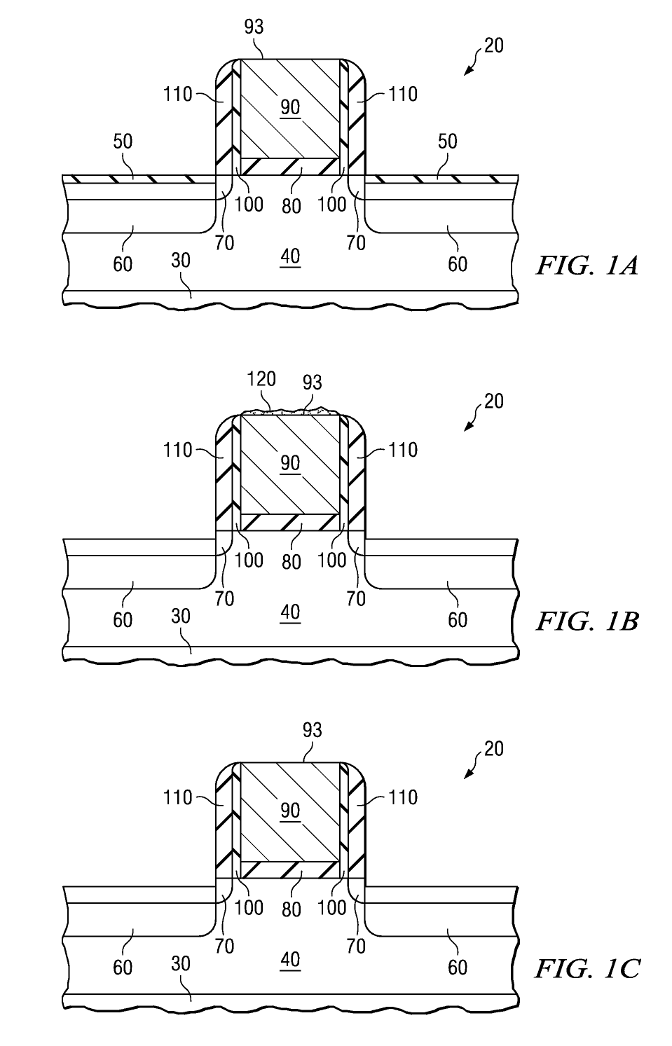

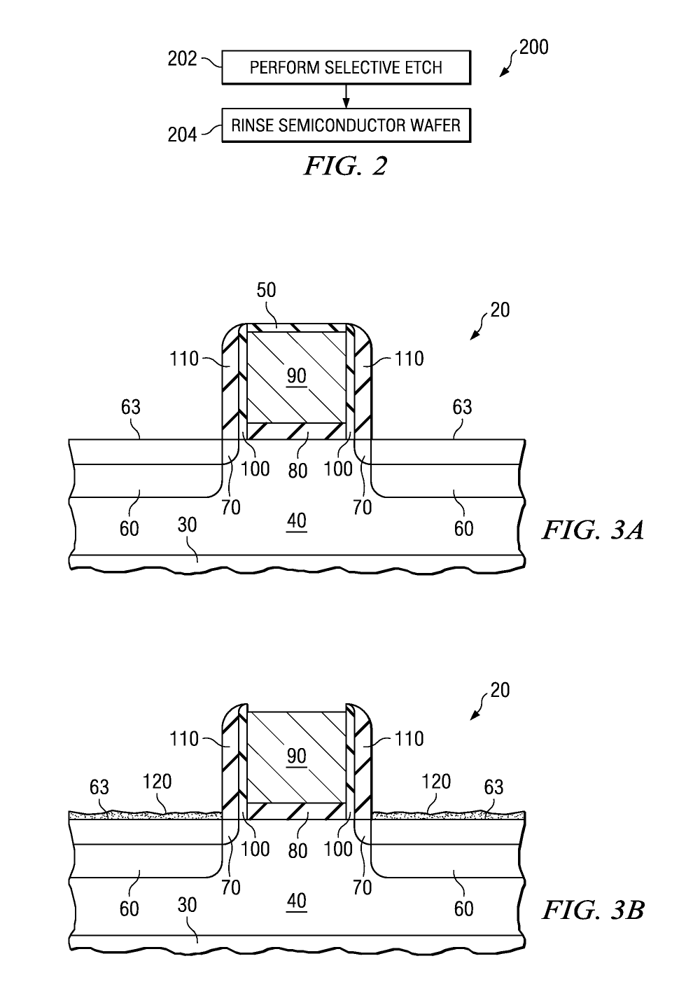

Referring to the drawings, FIGS. 1A-1C are cross-sectional views of a partially fabricated semiconductor wafer 20 illustrating a process for removing dielectric material from a semiconductor wafer in accordance with the present invention FIG. 2 is a corresponding flow chart illustrating the process flow of the invention. Other than the process steps shown in FIG. 2, the manufacturing process steps are those already used in the industry, such as the fabrication processes described in these commonly assigned patent applications: Ser. No. 10/808,168 (TI Docket Number TI-37782, filed Mar. 24, 2004), Ser. No. 10/810,759 (TI Docket Number TI-37793, filed Mar. 26, 2004), and Ser. No. 10/851,750 (TI Docket Number TI-37220, filed May 20, 2004). These patent applications are incorporated herein by reference but are not admitted to be prior art with respect to the present invention by their inclusion herein.

FIG. 1A is a cross-sectional view of a CMOS transistor structure after the formation of a silicided gate electrode 90. Specifically, at this stage in the manufacturing process the example semiconductor wafer 20 has a transistor that is comprised of a substrate 30, an oxide gate dielectric 80, a gate electrode a), extension sidewalls 100, spacer sidewalls 110, source/drain 60, and source/drain extensions 70. The gate electrode 90 may be either a partially silicided polysilicon gate electrode or a fully silicided gate electrode (“FUSI”). The top surface 93 of the gate electrode in exposed surface of the metal silicide 90. In this example application, the blanket layer of metal silicidation material that was used for the gate silicidation process was nickel. Therefore, the metal silicide 90 is comprised of NiSi₂.

Also a t this stage in the manufacturing process, the top surface of the source/drain 60 is comprised of a layer of dielectric material 50, such as SiO₂, that served as a blocking layer to protect the source/drain 6 from silicidation throughout the previous gate silicidation process. During that gate silicidation process, the semiconductor wafer was annealed, the blanket layer of silicidation material was removed, and then the semiconductor wafer was probably subjected to a second anneal in order to finalize the gate silicidation process.

In accordance with the invention, the next step is a selective etch process that removes the dielectric material 50 and also cleans debris from the semiconductor wafer 20 (step 202). This process is often called “deglazing”. This selective etch step is preferably a wet etch process using NE-14 as the etchant (produced and sold by Air Products & Chemicals, Inc. in Allentown, Pa.); however, the use of any organic semi-aqueous solvent-based etchant is within the scope of the invention. For example, the etchant may be EKC6910, EKC520 (both of which are sold by Du Pont EKC in Hayward Calif.), or Buffered Oxide Etch (“BOE” sold by Mallinckrodt-Baker in Phillipsburg, N.J.).

Any suitable machine may be used for the selective etch process 202, such as DNS SU3000 (for single wafer processing) or DNS FC300 (for batch processing), both of which are sold by Dai Nippon Screen (“DNS” in Yasu, Japan). The selective etch process may be carried out at any temperature between 25° C. and 100° C., however, the optimal temperature range for this step is 40-55° C.

This selective etch process has a one to one selectivity that removes the dielectric material 50without removing appreciable amounts of the metal silicide 90, as shown in FIG. 1B. Mechanistically, the amount of metal silicide removed during the selective etch step 202 is limited by the self-passivation of the surface 93 of the metal silicide 90. Once a thin layer of sediment 120is formed on the surface 93 of the metal silicide the gate electrode 90 is protected from further etching (i.e. the fluoride in NE-14 cannot further corrode the metal in the metal silicide electrode 90). Thus, the self-passivation of the metal silicide that occurs during the selective etch process 202 provides process predictability and improved process margins.

In accordance with the invention, the next step is a rinse (step 204). In the example application, the semiconductor wafer 20 is rinsed in-situ (using the same machine that was used for the selective etch process 202) with a standard deionized water rinse process; however, the use of any suitable rinse process and machine is within the scope of the invention. One benefit of the rinse step 204 is the removal of the sediment layer 120 from the surface 93 of the metal silicide 90, as shown in FIG. 1C.

The fabrication of the semiconductor wafer 20 now continues with any known process flow. For example, the next step may be the application of the source/drain silicidation layer in preparation for the silicidation of the source/drain 60, as described in patent application Ser. No. 10/808,168 (TI Docket Number TI-37782), which was incorporated supra.

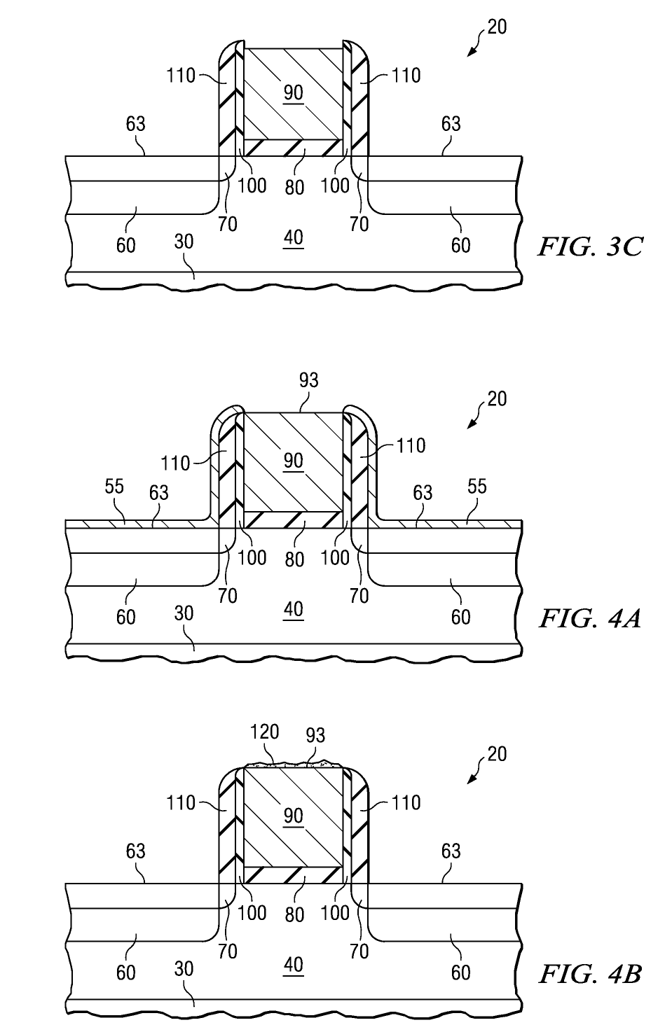

It is within the scope of the invention to use the process flow of the present invention with alternative wafer fabrication processes. For example, FIGS. 3A-3C are cross-sectional views of a partially fabricated semiconductor wafer 20 illustrating a process for removing dielectric material from a semiconductor wafer in accordance with another embodiment of the present invention.

FIG. 3A is a cross-sectional view of a CMOS transistor structure after the formation of silicided source/drain 60. Specifically, at this stage in the manufacturing process the example semiconductor wafer 20 has a transistor that is comprised of a substrate 30, an oxide gate dielectric 80, a gate electrode 90, extension sidewalls 100, spacer sidewalls 110, source/drain 60, and source/drain extensions 70. The source and drain 60 are silicided and have an exposed surface 63. In this example application, the blanket layer of metal silicidation material that was used for the source/drain silicidation process was cobalt. Therefore, the metal silicide 60 is comprised of CoSi₂.

Also at this stage in the manufacturing process, the top surface of the gate electrode 90 is comprised of a layer of dielectric material 50, such as SiO₂, that served as a blocking layer to protect the gate electrode 90 from silicidation throughout the previous source/drain silicidation process. During the source/drain silicidation process, the semiconductor wafer was annealed, the blanket layer of silicidation material was removed, and then the semiconductor wafer was probably subjected to a second anneal in order to finalize the source/drain silicidation process.

In accordance with the invention, the next step is the previously-described selective etch process 202. The selective etch will remove the dielectric material 50 from the gate electrode 90 and also clean debris from the semiconductor wafer 20, as shown in FIG. 3B. In addition, the selective etch process will remove the dielectric material 50 from the gate electrode 90 without removing appreciable amounts of the metal silicide 60. The self-passivation of the surface 63 of the metal silicide 60 will create a thin layer of sediment 1 20 that protects the source/drain 60 from further etching during the selective etch process 202.

In accordance with the invention, the next step is the previously-described rinse step 204. The rinse step 204will remove the sediment layer 120 from the surface of the metal silicide 60, as shown in FIG. 3C.

The fabrication of the semiconductor wafer 20 now continues with any known process flow. For example, the next step may be the application of the gate silicidation layer in preparation for the silicidation of the gate electrode 90, as described in patent application Ser. No. 10/810,759 (TI Docket Number-137793), which was incorporated supra.

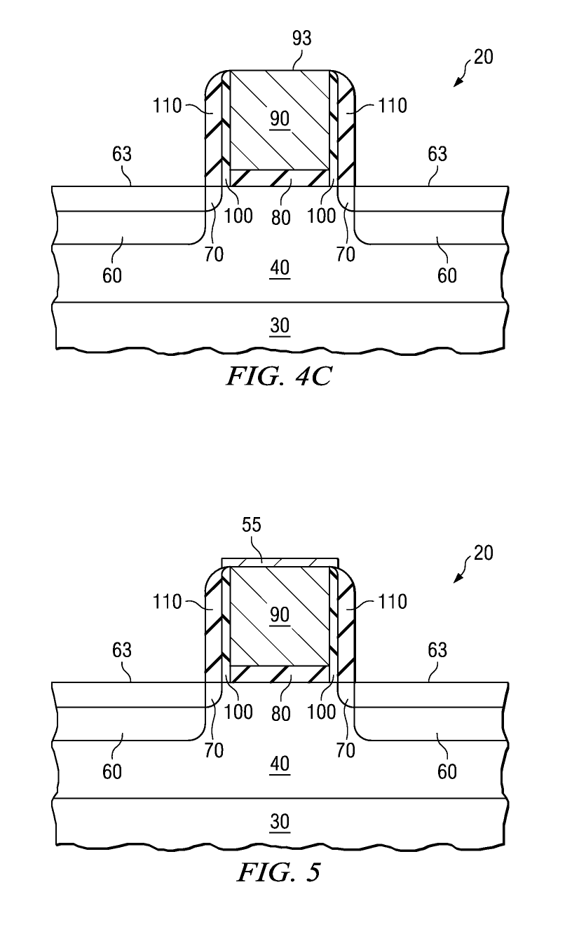

Another wafer fabrication process implementing the present invention is shown in FIGS. 4A-4C. These figures contain cross-sectional views of a partially fabricated semiconductor wafer 20 illustrating a process for removing dielectric material from a semiconductor wafer in accordance with another embodiment of the present invention.

FIG. 4A is a cross-sectional view of a CMOS transistor structure after the formation of a silicided get electrode 90 Specifically, at this stage in the manufacturing process the example semiconductor wafer 20 ha s a transistor that is comprised of a substrate 30, an oxide gate dielectric 80, a gate electrode 90, extension sidewalls 100, spacer sidewalls 110, source/drain 60, and source/drain extensions 70. In addition, the transistor structure has a mask layer 5 5 that was used to protect the source/drain 60 during the silicidation of the gate electrode 90. The mask layer 55 may be comprised of any suitable material such as titanium nitride or metal carbide. In this example application, the blanket layer of metal silicidation material that was used for the gate silicidation process was nickel. Therefore, the metal silicide 90 is comprised of NiSi₂.

In accordance with the invention, the next step is the previously-described selective etch process 202. The selective etch will remove the TiN mask 55 and also clean debris from the semiconductor wafer 20, as shown in FIG. 4B. Once again, the selective etch process will remove the mask material 55 without removing appreciable amounts of the metal silicide 90. The self-passivation of the surface 93 of the metal silicide 90 will create a thin layer of sediment 120 that protects the gate electrode 90 from further etching during the selective etch process 202.

In accordance with the invention, the next step is the previously-described rinse step 204. The rinse step 204 will remove the sediment layer 120 from the surface 93 of the metal silicide, as shown in FIG. 4C.

The fabrication of the semiconductor wafer 20 now continues with any known process flow. For example, the next step may be the application of the source/drain silicidation layer in preparation for the silicidation of the source/drain 60, as described in patent application Ser. No. 10/851,750 (TI Docket Number TI-37220), which was incorporated supra. Those skilled in the art can easily understand how this invention may be implemented when the mask 55 is used to protect the gate electrode 90 from the previous silicidation process, as shown in FIG. 5A, instead of protecting the source/drain 60 from the previous silicidation process, as shown in FIG. 4A.

Various additional modifications to the invention as described above are within the scope of the claimed invention. For example, instead of using SiO₂ for the dielectric layer 50, other dielectric materials, such as Si₃N₄ or spin-on-glass (“SOG” such as DUO that is sold by Honeywell in Chandler, Ariz.) may be used. In addition, the semiconductor wafer 20 may contain a mix of partially silicided polysilicon gate electrodes and FUSI gate electrodes. Moreover, the metal silicide feature 90, 60 may belong to other components, such as a metal resistor, a capacitor, or a diode.

While various embodiments of the present invention have been described above, it should be understood that they have been presented by way of example only, and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

What is claimed is:

1. A method for removing dielectric material from a semiconductor wafer having metal silicide, comprising:
performing a selective etch of said semiconductor wafer using an organic semi-aqueous solvent-based etchant until said dielectric material is substantially removed; and
rinsing said semiconductor wafer, including a surface of said metal silicide of said semiconductor wafer.

2. The method of claim 1 wherein said organic semi-aqueous solvent-based etchant comprises NE-14.

3. The method of claim 1 wherein said metal silicide comprises Ni.

4. The method of claim 1 wherein said metal silicide comprises Co.

5. The method of claim 1 wherein said metal silicide comprises a fully silicided gate electrode of a transistor.

6. The method of claim 1 wherein said metal silicide comprises a partially silicided polysilicon gate electrode of a transistor.

7. The method of claim 1 wherein said metal silicide comprises a source and a drain of a transistor.

8. The method of claim 1 wherein said metal silicide comprises a TiN mask of a transistor.

9. The method of claim 1 wherein said rinsing step comprises rinsing said semiconductor wafer with deionized water.

10. The method of claim 1 wherein said dielectric material comprises SiₓO_{y}.

11. The method of claim 1 wherein said dielectric material comprises SiₓN_{y}.

12. The method of claim 1 wherein said step of performing a selective etch comprises using a process temperature between 25-100° C.

13. The method of claim 1 wherein said step of performing a selective etch comprises using a process temperature between 40-55° C.

14. The method of claim 1 wherein said step of performing a selective etch results in deglazing said semiconductor wafer.

15. The method of claim 1 wherein said step of performing a selective etch causes said metal silicide to self-passivate.

16. The method of claim 1 wherein an etch selectivity of said dielectric material to said metal silicide is 1.0 to 1.0.
